(19) United States
(12) Patent Application Publication
(10) Pub. No.: US 2026/0194607 A1
(43) Pub. Date: Jul. 9, 2026

(54) Physical Security and Authentication Systems Using Quantum Signatures

(71) Applicant: Northeastern University, Boston, MA (US)

(72) Inventors: Swastik KAR, Belmont, MA (US); Arun BANSIL, Boston, MA (US); Paul STEVENSON, Boston, MA (US)

(21) Appl. No.: 19/132,479

(22) PCT Filed: Jan. 19, 2024
(86) PCT No.: PCT/US2024/012248

§ 371 Date: May 23, 2025

Related U.S. Application Data
(60) Provisional application No. 63/439,927, filed on Jan. 19, 2023.

(51) Int. Cl. G01R 33/12; B42D 25/369; B82Y 15/00; B82Y 25/00; B82Y 35/00; C08K 3/22; G01Q 60/20

(52) U.S. Cl. CPC G01R 33/1276; B42D 25/369; C08K 3/22; G01Q 60/20; B82Y 15/00; B82Y 25/00; B82Y 35/00; C08K 2003/2272; C08K 2201/01; C08K 2201/011

(57) ABSTRACT

Physical identification tags are provided that contain patterns of magnetized and non-magnetized nanoparticles embedded in a matrix. The magnetic nanoparticles form a spatially unique magnetic field distribution that is detectable only with the use of a quantum scanning magnetometer with nanometer resolution. The invisible magnetic field pattern is randomly generated by the mixture of magnetic with nonmagnetic nanoparticles and is physically impossible to reproduce. The tags can be used for identification and authentication of articles of commerce, artworks, and subjects.

### CROSS REFERENCE TO RELATED APPLICATIONS

This application claims the priority of U.S. Provisional Application No. 63/439,927, filed Jan. 19, 2023 and entitled “Physical Security and Authentication Systems Using Quantum Signatures”, the whole of which is hereby incorporated by reference.

### BACKGROUND

Global trade in fake goods is worth about $500 Bn per year. The current approach to combat this is to embed various types of physical security tags with unique identifiers to prevent counterfeiting/forgery. Such security tags include bar codes or QR-codes; RFIDs and magnetic stripe tags; and unique patterns of nanomaterials, 2D materials, or fluorescent materials. The problem with current physical security tags, however, is that counterfeiters employ substantial resources in locating and reverse-engineering (or, “breaking”) them. The impacts of counterfeiting are felt by owners, creators, manufacturers, and people or entities responsible for point-to-point authentication of valuable art, medicines, luxury items, currency, authentic aircraft parts, and other valuable objects, including museums, auction houses, shipping and transportation agencies, inspectors at ports of entry, storage and display agencies, and other stakeholders. What is needed are physical security tags having information that is as untraceable as possible, and as irreproducible as possible. Most existing physical security technologies are ineffective in meeting these criteria.

### SUMMARY

The present technology provides physical identification tags having patterns that are detectable only with the use of specialized quantum-based scanning probe microscope with nanometer resolution. The tags utilize a nearly invisible pattern of magnetic nanoparticles randomly mixed with nonmagnetic nanoparticles. The nanoscale quantum magnetic signatures of the tags are physically impossible to reproduce.

An aspect of the technology is a unique identification (UID) tag including a mixture of magnetic and non-magnetic nanoparticles embedded in a solid matrix, wherein the magnetic nanoparticles are distributed in a unique pattern within the matrix.

Another aspect of the technology is an object for sale, transport, storage, or identification or authentication of a subject or an article, wherein the object includes the UID tag of any of the preceding features.

Yet another aspect of the technology is a system including the UID tag described above and a reader device, wherein the reader device is capable of determining a spatial distribution pattern and/or magnetic field distribution pattern of the magnetic nanoparticles of the UID tag at nanometer scale resolution by quantum scanning magnetometry.

Still another aspect of the technology is a method of identifying an object or determining its authenticity. The method includes the following steps: (a) providing the system described above and said object; (b) scanning the object or a portion thereof using a quantum scanning magnetometer to detect a spatial distribution and/or a magnetic field distribution of magnetic nanoparticles in an UID tag attached to or embedded within the object; and (c) comparing the result of (b) with the database, whereby the object is identified or authenticated if a spatial and/or magnetic field distribution pattern of a UID tag of the object matches that of a UID tag in the database.

The present technology can be further summarized with the following list of features.
1. A unique identification (UID) tag comprising a mixture of magnetic and non-magnetic nanoparticles embedded in a solid matrix, wherein the magnetic nanoparticles are distributed in a unique pattern within the matrix.
2. The UID tag of feature 1, wherein the unique pattern comprises a two-dimensional or three-dimensional spatial distribution of magnetic nanoparticles dispersed within a plurality of non-magnetic nanoparticles.
3. The UID tag of feature 2, wherein the magnetic nanoparticles are indistinguishable from the non-magnetic nanoparticles by electron microscopy or atomic force microscopy.
4. The UID tag of any of the preceding features, wherein the magnetic field of the magnetic nanoparticles is detectable by a quantum scanning magnetometer at a distance in the range from about 10 nanometers to about 100 nanometers.
5. The UID tag of any of the preceding features, wherein the magnetic nanoparticles possess a magnetic field strength of less than or equal to 100 microtesla at a distance of about 100 nm.
6. The UID tag of any of the preceding features, wherein the magnetic nanoparticles comprise or consist of Fe, Ni, V, Co, or Ni, or oxides thereof, such as Fe₃O₄.
7. The UID tag of any of the preceding features, wherein the magnetic field of the magnetic nanoparticles is not detectable by magnetic force microscopy.
8. The UID tag of any of the preceding features, wherein the matrix comprises a polymer material.
9. An object for sale, transport, storage, or identification or authentication of a subject or an article, wherein the object comprises the UID tag of any of the preceding features.
10. A system comprising the UID tag of any of features 1-8 and a reader device, wherein the reader device is capable of determining a spatial distribution pattern and/or magnetic field distribution pattern of the magnetic nanoparticles of the UID tag at nanometer scale resolution by quantum scanning magnetometry.
11. The system of feature 10, wherein the reader device is a nitrogen vacancy magnetometer.
12. The system of feature 11, wherein the nitrogen vacancy magnetometer is a scanning probe microscope comprising a diamond probe comprising said nitrogen vacancy, a microwave source capable of manipulating a quantum spin state of said nitrogen vacancy, and an optical probe capable of detecting a fluorescence output signal from the probe.
13. The system of any of features 10-12, further comprising a plurality of said UID tags and a database comprising a predetermined spatial and/or magnetic field distribution pattern, or a parameter derived therefrom by an algorithm, for each of the plurality of UID tags.
14. The system of feature 13, wherein the nitrogen vacancy magnetometer or a computer associated therewith comprises a trained artificial intelligence capable of identifying any of the plurality of UID tags.
15. A method of identifying an object or determining its authenticity, the method comprising:
   (a) providing the system of feature 13 or feature 14 and said object;
   (b) scanning the object or a portion thereof using a quantum scanning magnetometer to detect a spatial distribution and/or a magnetic field distribution of magnetic nanoparticles in an UID tag attached to or embedded within the object; and
   (c) comparing the result of (b) with the database, whereby the object is identified or authenticated if a spatial and/or magnetic field distribution pattern of a UID tag of the object matches that of a UID tag in the database.
16. The method of feature 15, further comprising, prior to step (b), exposing the UID tag to a magnetic field capable of magnetizing the magnetic nanoparticles to a field strength in a range from about 1 nanotesla to about 1000 microtesla at a distance of about 100 nm.

### BRIEF DESCRIPTION OF DRAWINGS

FIG. 1 is a schematic illustration of a unique identification tag (UID) according to the present technology.

FIG. 2 is a schematic illustration of the neutral appearance of a UID of the present technology when visualized by the unaided human eye or even an ordinary light microscope. Neither magnetic nor non-magnetic nanoparticles can be detected.

FIG. 3 is a schematic illustration of the appearance of a UID of the present technology when viewed with the aid of an electron microscope, such as a scanning electron microscope (SEM). While in principle all nanoparticles can be detected against the blank matrix background, magnetic nanoparticles cannot be distinguished from non-magnetic nanoparticles, and no magnetic field pattern is apparent.

FIG. 4 is a schematic illustration of the pattern of magnetic field that can be detected using a scanning nitrogen vacancy (SNV) microscope or similar instrument. The figure depicts magnetic field lines surrounding each magnetic nanoparticle.

FIG. 5 is a schematic illustration of an SNV microscope. Derived from US 2015/0253355, which is incorporated herein by reference in its entirety.

### DETAILED DESCRIPTION

The present technology provides unclonable physical security tags and authentication labels using nearly invisible, quantum signatures of nanomagnets. The technology uses nanoscale or microscale quantum magnetic signatures which are physically impossible to reproduce, and which are readable only with highly sophisticated readout devices.

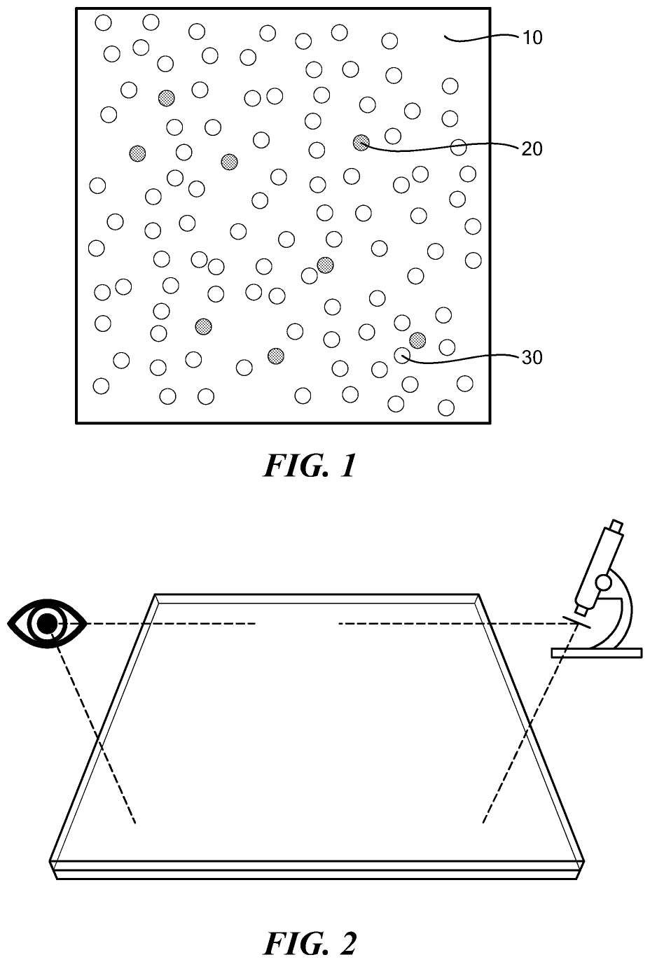

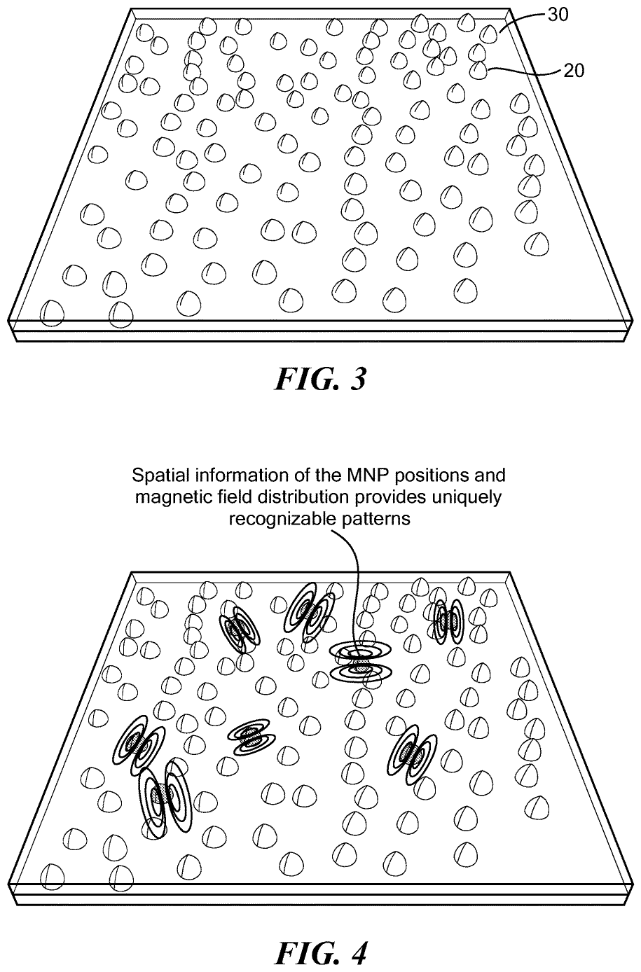

The technology provides a new type of unique identifying (UID) tag The UID tag contains commercially available, magnetic or magnetizable nanoparticles (MNPs) that possess very low magnetic fields in their immediate vicinity. The MNPs are randomly mixed with non-magnetic nanoparticles that are similar or identical in size and shape. The mixed nanoparticles (NPs) can be embedded in a solid matrix, which can be either rigid or flexible. FIG. 1 shows an illustration of such a UID. A mixture of magnetic nanoparticles 20 and non-magnetic nanoparticles 30 is randomly distributed within or attached to a surface of matrix 10. The random distribution of MNPs among nonmagnetic NPs, and their magnetic field distribution together form an unclonable and uniquely distinguishable pattern in two dimensions or three dimensions. When the UID is viewed with the unaided human eye or with a light microscope, no nanoparticles can be detected, as represented in FIG. 2; this assures that unsophisticated copyists will not be able to find a pattern to try to copy. Even if access to a scanning electron microscope is available, which can image and detect the nanoparticles (see FIG. 3), it will not be able to detect the magnetic fields of the magnetic nanoparticles or a 2-D or 3-D magnetic field pattern formed by the magnetic nanoparticles within the UID. The 2-D or 3-D pattern can include the spatial positions of the magnetic nanoparticles as well as the magnetic field strength and orientation (see FIG. 4).

The magnetic field pattern and/or magnetic particle position pattern of UID tags can be detected, for example, using a scanning NV (SNV) microscope, or a specially adapted version thereof configured as a UID reader. A reader device can, for example, include multiple NV tips to speed up the process of scanning tags. The SNV reader is over 200 times more sensitive than current magnetic force microscopy (MFM) technologies, and enables concealment of UID information using magnetic signals at least 200-fold weaker. This offers the key ability to reliably read MNP-based UIDs that are invisible to the naked eye, light microscopes, MFMs, and any other type of reader.

The UID reader employs recognition software for reading and storing the UID signature of MNPs measured by the SNV reader/microscope. Spatial coordinates using image comparison techniques would be used to compare the coordinates of magnetic nanoparticles. Optionally, alignment markers or reference points can be pre-patterned on the tag to establish a physical coordinate system. Point-to-point correlation of magnetic fields with respect to a reference pattern can be determined, with minimum criteria selected to determine a match. For example, in some use-cases, pattern similarities exceeding 90% can be considered sufficient, while in other applications at least 99.99% might be considered an acceptable match, according to the needs of the user. Artificial intelligence (AI) learning can be incorporated to provide AI-based pattern-recognition algorithms. For example, a large set of tags numbering in the thousands, tens of thousands, or hundreds of thousands can be prepared, and magnetic field scans performed on each tag of the set. The pattern data can be used to train the AI, which will then be able to readily identify any individual tag in the set when tested in the field. A variety of AI-based algorithms are available for detecting 2-D or 3-D patterns of particles, and many such known algorithms and methods can be used to detect MNP patterns in the present UIDs. See, for example, J. M. Newby et al., Proc. Natl. Acad. Sci. 115:(2018), doi/10.1073/pnas.1804420115. A convolutional neural network can be trained using a set of UIDs, which can then be later identified rapidly and with high accuracy using magnetic field data obtained using an SNV microscope or reader device.

In use, the UID physical security tags can be embedded into or onto any object of value. A magnetic fingerprint dataset for each tag can be made available to a service provider, who can use the UID reader and a database to authenticate an object. Unlike conventional physical security tags, UID tags of the present technology cannot be reverse engineered or tampered with, and will be virtually impossible to falsify. In this way, key problems facing previous physical security devices are overcome.

A wide variety of permanently magnetic or magnetizable nanoparticles, including many that are commercially available, can be used as the MNPs of the present technology. The magnetic nanoparticles should have a magnetic field in the range of nanotesla to microtesla, i.e., from about 1 nanotesla to about 1000 microtesla. Nanoparticles containing or consisting of Fe, Ni, V, Co, or Ni, or oxides thereof, such as, for example, Fe₃O₄ nanoparticles, can be used as the MNPs. Such nanoparticles exhibit very low magnetic fields (<100 microtesla) in their immediate vicinity (i.e., within 100 nanometers). These MNPs can be randomly mixed with physically identical or nearly identical non-magnetic particles and embedded in a solid matrix, which can be either rigid or flexible (FIG. 1). Various methods for mixing and embedding can be used, including dispersion into a liquid phase, ultrasonic mixing or other methods for mixing, and subsequently distributed as embedded within or attached on a surface of a matrix material or substrate by any of a variety of techniques, including spin coating, drop-casting, dip coating, or other liquid-dispersion techniques including spray, electrospray, and aerosol application. A solid dispersion of a mixture of magnetic and non-magnetic nanoparticles also can be prepared, and then mixed with a matrix-forming material, such as a polymerizable resin. The matrix material, containing the mixture of nanoparticles, can then be poured from a fluidic state (e.g., a polymer melt or epoxy mixture) and solidified. The goal is to obtain random distributions of mixed nanoparticles well-separated from each other and embedded approximately 10-100 nanometers below the top surface of the matrix. This composite structure can be self-standing or can be mounted on a supporting material and attached to or embedded discretely into the object being protected (i.e., work of art, luxury item, ID card, or currency). The random distribution of magnetic particles distributed among nonmagnetic nanoparticles forms a uniquely distinguishable pattern. Large batches of such tags each with unique MNP maps can be fabricated.

The UID tag can be formed to any desired size, shape, and thickness, and it can be labeled or encased within a housing as desired, such as for protection of the nanoparticles or for attachment to an object to be uniquely labeled or identified with the tag.

The unique pattern encoded in each individual tag is generated by the natural randomness of the nanoparticle dispersion process. It cannot be intentionally programmed and hence this pattern is virtually impossible to reproduce. This provides the highest level of security against any currently available or even conceivable technology that could be used for tampering or reverse-engineering these tags.

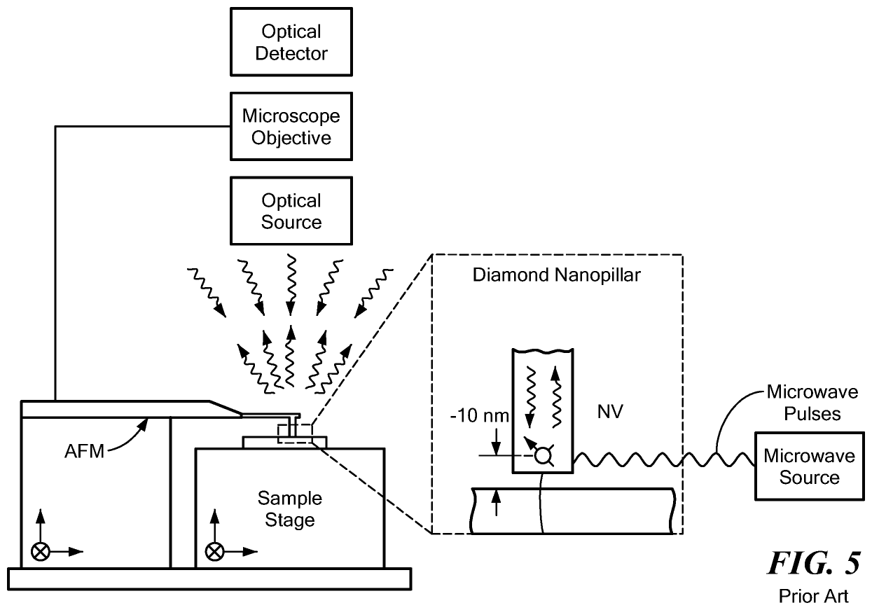

The SNV microscope used for detection and readout is a quantum microscope capable or measuring microtesla-level magnetic fields and independently imaging magnetic nanoparticle position with a nanoscale resolution. An example of a commercially available SNV microscope is the QNAMI PROTEUS Q scanning NV magnetometer (www.horiba.com/en_en/nv-magnetometry/). NV magnetometry involves use of a nitrogen vacancy (NV) center in a diamond probe incorporated into a scanning probe microscope. The SNV microscope is different from the MFM microscope, which uses a conventional atomic force microscope in which the probe is coated with a magnetic material, thereby altering the force detected in the presence of a magnetic field. With the SNV microscope, the diamond probe containing a nitrogen vacancy, when positioned close to a magnetic field of appropriate intensity. See, for example, FIG. 5. A microwave source is used to manipulate the spin state of the nitrogen vacancy, and an optical signal (fluorescence) is generated for detection of a magnetic field. The use of a scanning probe microscope allows nanometer level spatial resolution (i.e., resolution limit from about 1 nm to about 1000 nm) of magnetic fields on a sample surface.

The SNV microscope enables a greater amount of identifying information to be determined than previous methods, owing to its much higher sensitivity to low magnetic fields. The SNV microscope allows reliably reading and recognizing MNP-based UIDs that are hidden from any other type of readers. Data generated by the microscope can be used to create a database for each tag or group of tags for future comparisons under testing conditions.

Users can routinely develop their own UID recognition program/software for reading and storing the spatial pattern of magnetic field distributions of the MNPs measured by the SNV microscope from a UID label or tag and storing this information securely to create a fingerprint training dataset for the label or tag. The same program can also be used to read similar data from a tag under test conditions. One or more machine-learning based pattern-recognition algorithm(s) can be uniquely trained on the full database of labels/tags and subsequently used to uniquely identify selected tags with respect to the trained dataset, thereby uniquely confirming the identity of a tested item as authentic, or failing to confirm it as belonging to the trained dataset and therefore identifying it as a suspected counterfeit item.

Physical UID security tags with unique patterns can be embedded into or attached to an object of value. The fingerprint dataset will be available to a service provider. When the authenticity of the object of value needs to be verified, the service provider uses the quantum microscope to read the label/tag and compares it with the known fingerprint database. A fingerprint can be a distribution map of magnetizable or magnetized nanoparticles, together with independent information about the magnetic field at each particle, or these parameters can be combined using an algorithm to produce a score, matrix, graphic, or map for use in identification. Authentication occurs when the pattern recognition algorithm is able to match the data from the tested tag with its counterpart stored in the database.

In UID tags of the present technology, the nanoparticles in the matrix are invisible to the naked eye or to conventional light microscopes (FIG. 2), providing a basic layer of security against recognition or tampering. Even electron microscopes, such as scanning electron microscopes, cannot detect the magnetic field patterns even though they can visualize the mixed nanoparticles and their physical distribution. In the absence of an SNV microscope or special purpose reader with similar functionality, the MNPs are completely hidden among non-magnetizable nanoparticles and hence not recognizable even with a scanning electron microscope (FIG. 3), or with other forms of high resolution microscopy (e.g., transmission electron microscopy (TEM), scanning transmission electron microscopy (STM), or atomic force microscopy (AFM)), providing a high security barrier against tampering.

The unique pattern of magnetizable nanoparticles encoded in a UID tag is randomly generated and cannot be copied. The pattern (i.e., magnetic field distribution and MNP positions) is only detectable to a quantum imaging magnetometer (see FIG. 4) due to the small particle size and low magnetic field strength of the MNPs. This provides the highest level or security against any currently conceivable technology that could be used for tampering or reverse-engineering the tags. The chemical composition of MNPs and matrix materials, as well as the magnetic properties of the MNPs, can be selected to produce magnetic field distributions that either last very long (e.g., extremely delicate objects that cannot be re-tagged frequently) or decay with time (e.g., to provide time duration information if desired).

There are many uses for the UIDs, quantum magnetometer readers, and systems of the present technology. They can be used for authentication of expensive art, antiques, and heritage objects at museums, exhibitions, auctions, and the like. They can be used to prevent counterfeit medicine and currency at ports of entry. They can be used to assist blockchain authentication of in-transit aircraft parts and other parts by high-tech defense manufacturers. They can be used by manufacturers to certify expensive luxury items. The technology also can be used for identifying individual people (e.g., can be placed in identification cards, badges, licenses, or passports) or animals, and to provide secure IDs for VIPs at high-security buildings or special events.

The present technology includes the following novel aspects.
(a) The nanoparticles in the matrix are invisible to the naked eye or conventional microscopes, providing a basic layer or security against rapid recognition or tampering.
(b) In the absence of an SNV or similar microscope, the MNPs are completely hidden among non-magnetizable nanoparticles and hence not recognizable under more sophisticated tools such as an SEM, providing a high security barrier against tampering.
(c) A unique pattern is generated by the natural randomness of nanoparticle dispersion process. It cannot be intentionally programmed and hence is virtually impossible to reproduce. This provides the highest level or security against any currently-conceivable technologies that could be used to prevent tampering or reverse-engineering of the tags.
(d) An SNV microscope or similar device reads both spatial distribution of MNPs and (independently) their magnetic field distribution (FIG. 4). The combination of spatial arrangement and magnetic field distribution as independent layers of distinguishable patterns provides a complex, difficult to reproduce signature.
(e) Choosing different MNPs and matrix materials can result in magnetic field distributions that can either last very long (e.g., for use with extremely delicate objects that cannot be re-tagged frequently) or decay with time (e.g., to provide time-duration information for time-sensitive objects of value to if required).

As used herein, “consisting essentially of” allows the inclusion of materials or steps that do not materially affect the basic and novel characteristics of the claim. Any recitation herein of the term “comprising”, particularly in a description of components of a composition or in a description of elements of a device, can be exchanged with “consisting essentially of” or “consisting of”.

While the present invention has been described in conjunction with certain preferred embodiments, one of ordinary skill, after reading the foregoing specification, will be able to effect various changes, substitutions of equivalents, and other alterations to the compositions and methods set forth herein.

1. A unique identification (UID) tag comprising a mixture of magnetic and non-magnetic nanoparticles embedded in a solid matrix, wherein the magnetic nanoparticles are distributed in a unique pattern within the matrix.

2. The UID tag of claim 1, wherein the unique pattern comprises a two-dimensional or three-dimensional spatial distribution of magnetic nanoparticles dispersed within a plurality of non-magnetic nanoparticles.

3. The UID tag of claim 2, wherein the magnetic nanoparticles are indistinguishable from the non-magnetic nanoparticles by electron microscopy or atomic force microscopy.

4. The UID tag of claim 1, wherein the magnetic field of the magnetic nanoparticles is detectable by a quantum scanning magnetometer at a distance in the range from about 10 nanometers to about 100 nanometers.

5. The UID tag of claim 1, wherein the magnetic nanoparticles possess a magnetic field strength of less than or equal to 100 microtesla at a distance of about 100 nm.

6. The UID tag of claim 1, wherein the magnetic nanoparticles comprise or consist of Fe, Ni, V, Co, or Ni, or oxides thereof, such as Fe3O4.

7. The UID tag of claim 1, wherein the magnetic field of the magnetic nanoparticles is not detectable by magnetic force microscopy.

8. The UID tag of claim 1, wherein the matrix comprises a polymer material.

9. An object for sale, transport, storage, or identification or authentication of a subject or an article, wherein the object comprises the UID tag of claim 1.

10. A system comprising the UID tag of claim 1 and a reader device, wherein the reader device is capable of determining a spatial distribution pattern and/or magnetic field distribution pattern of the magnetic nanoparticles of the UID tag at nanometer scale resolution by quantum scanning magnetometry.

11. The system of claim 10, wherein the reader device is a nitrogen vacancy magnetometer.

12. The system of claim 11, wherein the nitrogen vacancy magnetometer is a scanning probe microscope comprising a diamond probe comprising said nitrogen vacancy, a microwave source capable of manipulating a quantum spin state of said nitrogen vacancy, and an optical probe capable of detecting a fluorescence output signal from the probe.

13. The system of claim 10, further comprising a plurality of said UID tags and a database comprising a predetermined spatial and/or magnetic field distribution pattern, or a parameter derived therefrom by an algorithm, for each of the plurality of UID tags.

14. The system of claim 13, wherein the nitrogen vacancy magnetometer or a computer associated therewith comprises a trained artificial intelligence capable of identifying any of the plurality of UID tags.

15. A method of identifying an object or determining its authenticity, the method comprising:
(a) providing the system of claim 13 and said object;
(b) scanning the object or a portion thereof using a quantum scanning magnetometer to detect a spatial distribution and/or a magnetic field distribution of magnetic nanoparticles in an UID tag attached to or embedded within the object; and
(c) comparing the result of (b) with the database, whereby the object is identified or authenticated if a spatial and/or magnetic field distribution pattern of a UID tag of the object matches that of a UID tag in the database.

16. The method of claim 15, further comprising, prior to step (b), exposing the UID tag to a magnetic field capable of magnetizing the magnetic nanoparticles to a field strength in a range from about 1 nanotesla to about 1000 microtesla at a distance of about 100 nm.
